(19) United States
(12) Patent Application Publication
(10) Pub. No.: US 2026/0177904 A1
(43) Pub. Date: Jun. 25, 2026

(54) MASK PATTERN DETERMINATION METHOD, APPARATUS, MEDIUM, AND PRODUCT

(71) Applicant: DONGFANG JINGYUAN ELECTRON CO., LTD., Beijing (CN)

(72) Inventors: Shengrui Zhang, Beijing (CN); Zongqiang Yu, Beijing (CN); Weijie Shi, Beijing (CN); Hangyu Wang, Beijing (CN); Fengsheng Zhao, Beijing (CN); Yanbin Gong, Beijing (CN)

(21) Appl. No.: 19/545,660

(22) Filed: Feb. 20, 2026

(30) Foreign Application Priority Data
Mar. 11, 2025 (CN) 202510287626.3

(51) Int. Cl. G03F 1/36; G06T 7/00

(52) U.S. Cl. CPC G03F 1/36; G06T 7/0004; G06T 2207/20081; G06T 2207/20084; G06T 2207/20221; G06T 2207/30148

(57) ABSTRACT

The present application discloses a mask pattern determination method, a mask pattern determination apparatus, a medium, and a product, which are applied to the technical field of semiconductor. In this method, etching bias is determined by a first etch pattern and a first photolithography pattern, and the first etch pattern is obtained by merging the first sub-image and the second sub-image. The first sub-image is generated by a physical effect simulation unit based on the first photolithography pattern, and the second sub-image is generated by a neural network unit based on the first photolithography pattern. The neural network unit can effectively improve a data fitting ability of an etching model, thereby improving an accuracy of the etching model to obtain an accurate first etching bias. Meanwhile, the physical effect simulation unit of the etching model simulates an actual physical effect, which can prevent the etching model from over-fitting.

### CROSS-REFERENCE TO RELATED APPLICATIONS

This application claims priority to Chinese Patent Application No. 202510287626.3, filed on Mar. 11, 2025, which is hereby incorporated by reference in its entirety.

### TECHNICAL FIELD

The present application relates to the technical field of semiconductor, and in particular to a mask pattern determination method, apparatus, medium, and product.

### BACKGROUND

The core step of semiconductor chip manufacturing is to transfer a designed pattern of a chip to a wafer silicon. Among the multiple process steps of chip manufacturing, the processes directly related to the pattern transfer are mainly photolithography and etching. Both the photolithography process and the etching process will produce bias, which will bring about difference among the mask pattern, the photoresist pattern, and the etch pattern. Therefore, when designing the mask pattern, it is necessary to compensate the photolithography bias and the etching bias. Currently, the photolithography bias is mainly compensated using Optical Proximity Correction (OPC) method. For the etching bias, currently, an Etching Bias-Table is mainly established to store etching biases corresponding to different patterns, and then the corresponding etching bias is retrieved from the Etching Bias-Table based on the corresponding pattern types. For example, the corresponding etching bias is determined according to the line width and space of the edges of a current polygon, and then etching bias compensation is performed.

### SUMMARY

In one aspect, some embodiments of the present application provide a mask pattern determination method, which comprises: determining a first mask pattern based on a first target etch pattern; acquiring a first photolithography pattern after photolithography of the first mask pattern; inputting the first photolithography pattern to at least one physical effect simulation unit of an etching model to obtain at least one first sub-image correspondingly, and inputting the first photolithography pattern to a neural network unit of the etching model to obtain a second sub-image, the neural network unit being trained based on a photolithography pattern sample and a corresponding etch image label; merging the at least one first sub-image and the second sub-image by a merging unit of the etching model to obtain a first etch pattern after an etching process with the first photolithography pattern; determining a first etching bias of the first photolithography pattern based on the first etch pattern and the first photolithography pattern; and determining a first target mask pattern based on the first etching bias and the first target etch pattern.

Optionally, the determining a first target mask pattern based on the first etching bias and the first target etch pattern comprises: compensating the first target etch pattern based on the first etching bias, so as to obtain a first target photolithography pattern; performing optical proximity correction based on the first target photolithography pattern, so as to obtain a second mask pattern; updating the first mask pattern to the second mask pattern in a case that the first etching bias does not satisfy a first preset condition, and returning to the step of acquiring a first photolithography pattern after photolithography of the first mask pattern until the first etching bias satisfies the first preset condition; and determining the current second mask pattern as the first target mask pattern in a case that the first etching bias satisfies the first preset condition.

Optionally, the determining a first mask pattern based on a first target etch pattern comprises: determining a corresponding second etching bias based on the first target etch pattern and a first correspondence relationship, the first correspondence relationship being a correspondence relationship between an etch pattern and an etching bias; compensating the first target etch pattern based on the second etching bias to obtain a corresponding first target photolithography pattern; and performing optical proximity correction based on the first target photolithography pattern to obtain the first mask pattern.

Optionally, after the merging the at least one first sub-image and the second sub-image by a merging unit of the etching model, the method further comprises: acquiring a first target etch pattern corresponding to the first mask pattern; constructing a training sample according to the first target etch pattern and the first etch pattern; and performing model training according to the training sample to obtain a photolithography compensation and photolithography etching model.

Optionally, after the performing model training according to the training sample to obtain a photolithography compensation and photolithography etching model, the method further comprises: determining a second target photolithography pattern based on a second target etch pattern; inputting the second target photolithography pattern to the photolithography compensation and photolithography etching model to obtain a second etch pattern, and inputting the second target photolithography pattern to a pre-trained photolithography compensation and photolithography model to obtain a second photolithography pattern; determining a third etching bias based on the second etch pattern and the second photolithography pattern; in a case that the third etching bias does not satisfy the second preset condition, compensating the second target etch pattern based on the third etching bias to obtain a corrected second target photolithography pattern; updating the second target photolithography pattern to the corrected second target photolithography pattern, and returning to the step of inputting the second target photolithography pattern to the photolithography compensation and photolithography etching model to obtain a second etch pattern, and inputting the second target photolithography pattern to a pre-trained photolithography compensation and photolithography model to obtain a second photolithography pattern until the third etching bias satisfies the second preset condition; and determining a second target mask pattern based on a current corrected second target photolithography pattern in a case that the third etching bias satisfies the second preset condition.

Optionally, the determining a second target photolithography pattern based on a second target etch pattern comprises: determining a corresponding fourth etching bias based on the second target etch pattern and a first correspondence relationship, the first correspondence relationship being a correspondence relationship between an etch pattern and an etching bias; and compensating the second target etch pattern based on the fourth etching bias to obtain a corresponding second target photolithography pattern.

Optionally, before the inputting the first photolithography pattern to at least one physical effect simulation unit of an etching model to obtain at least one first sub-image correspondingly, and inputting the first photolithography pattern to a neural network unit of the etching model to obtain a second sub-image, the method further comprises: acquiring the photolithography pattern sample and the corresponding etch image label; inputting the photolithography pattern sample to the at least one physical effect simulation unit to obtain at least one third sub-image correspondingly, and inputting the photolithography pattern sample to an original neural network unit to obtain a fourth sub-image; merging the at least one third sub-image and the fourth sub-image by the merging unit to obtain a second etch image after an etching process with the photolithography pattern sample; acquiring a dimension difference between a first pattern critical dimension of the etch image label and a second pattern critical dimension of the second etch image; training the original neural network unit based on the dimension difference to obtain the neural network unit; and determining the etching model according to the neural network unit, the physical effect simulation unit, and the merging unit.

In another aspect, some embodiments of the present application provide a mask pattern determination apparatus, which comprises a processor and a memory storing computer program instructions, wherein the processor, when executes the computer program instructions, implements the aforesaid mask pattern determination method.

In still another aspect, some embodiments of the present application provide a non-transitory computer-readable storage medium, storing computer program instructions, when executed by a processor, implement the aforesaid mask pattern determination method.

In yet another aspect, some embodiments of the present application provide a computer program product, wherein instructions in the computer program product, when executed by a processor of an electronic device, enable the electronic device to execute the aforesaid mask pattern determination method.

### BRIEF DESCRIPTION OF THE DRAWINGS

In order to explain the technical solutions of the embodiments of the present application more clearly, the drawings required to be used in the embodiments of the present application will be briefly introduced below. For those skilled in the art, other drawings can be derived from these drawings without inventive efforts.

FIG. 1 shows a flow chart of a mask pattern determination method according to an embodiment of the present application;

FIG. 2 shows a schematic view of a model simulation process according to an embodiment of the present application;

FIG. 3 shows a first flow chart of designing a first target mask pattern according to an embodiment of the present application;

FIG. 4 shows a second flow chart of designing a first target mask pattern according to an embodiment of the present application;

FIG. 5 shows a first flow chart of designing a second target mask pattern according to an embodiment of the present application;

FIG. 6 shows a second flow chart of designing a second target mask pattern according to an embodiment of the present application;

FIG. 7 shows a flow chart of training an etching model according to an embodiment of the present application;

FIG. 8 shows a schematic structural view of a mask pattern determination apparatus according to an embodiment of the present application; and

FIG. 9 shows a schematic structural view of a hardware of a mask pattern determination apparatus according to an embodiment of the present application.

### DETAILED DESCRIPTION

Features and exemplary embodiments of various aspects of the present application will be described in detail below. In order to make the objects, technical solutions and advantages of the present application more clear, the present application will be further described in detail below with reference to the drawings and specific embodiments. It should be understood that, the specific embodiments described herein are only intended to explain the present application, but not to limit the present application. For those skilled in the art, the present application may be implemented without some of those specific details. The following description of the embodiments is only for providing a better understanding of the present application by showing examples.

It should be noted that, relational terms such as first, second, and the like are used herein merely for distinguishing one entity or operation from another without necessarily requiring or implying any such actual relationship or order between such entities or operations. Moreover, the terms “include”, “comprise”, or any other variation thereof, are intended to cover a non-exclusive inclusion, so that a(n) process, method, article or device that includes a series of elements not only includes those elements but also includes other elements not explicitly listed or also includes elements inherent to such process, method, article or device. An element preceded by “include . . . ” does not, without more constraints, preclude the existence of additional identical elements in the process, method, article or device that includes the element.

In current mainstream integrated circuit production process, photolithography technology works by using photoresist that undergoes chemical reactions when exposed to light of special wavelength, and then a pattern designed on a mask is transferred into a photoresist morphology (i.e., photolithography pattern) on a silicon wafer through development. While, the etching process selectively removes unwanted materials with the assistance of the photoresist pattern, thereby creating a desired fine pattern on the silicon wafer.

With continuous development of chip technology node, the design pattern dimension is much smaller than the photolithography wavelength (193 nm), which leads to optical proximity effect and photolithography bias. Thus, optical proximity correction (OPC) should be performed to compensate the photolithography bias.

However, in a manufacturing process of integrated circuit, an etching process should be further performed after photolithography process. The etching process may cause etching bias, that is, the photoresist line width before etching process is different from that after etching process. For example, when a wafer contains both sparse and dense patterns to be etched, an etching rate in dense areas is lower than an etching rate in sparse areas, which is called micro-loading effect. For another example, during the etching process of high aspect ratio structure, such as deep hole or deep groove, an etching rate of a hole or a groove with a smaller dimension is lower than an etching rate of a hole or a groove with a larger dimension, which is called aperture effect.

It can be seen that, different areas may correspond to different etching rates, which may lead to changes in the overall pattern dimension after etching, and more importantly, patterns with the same dimension after photolithography may also have different dimensions after etching. When designing the mask pattern, etching bias must be considered. Otherwise, even if the dimension of the photolithography pattern obtained after photolithography exposure meets the expectation, the pattern may still deviate from a target dimension after etching.

For the etching bias, currently, an Etching Bias-Table is mainly established to store etching biases corresponding to different patterns, and then the corresponding etching bias is retrieved from the Etching Bias-Table based on the corresponding pattern types. For current Bias-Table, the corresponding etching bias is determined according to the line width and space of the edges of a current polygon. For simple patterns, the requirements can be barely met, but when the patterns become complex, the accuracy of the conventional method may become low.

For two edges with exactly the same line width and the same space, if the pattern densities around them are different, the final etching biases may also be different. Thus, matching etching bias according to the existing Bias-Table method may inevitably lead to errors. With the continuous evolution of semiconductor technology node, the accuracy requirement for pattern transfer (photolithography and etching) is becoming increasingly high. However, a traditional method cannot meet the actual requirement.

Considering that the accuracy of the Bias-Table method is relatively low, in order to solve this problem, the present application proposes establishing an etching model to simulate an etching process. After simulating an etch image, an etching bias can be determined based on the pattern in the etch image. First, a physical effect simulation unit Term can be provided to construct a part of the model based on physical effect actually produced during the etching process. Since the accuracy of etching simulation only through the physical effect simulation unit Term is insufficient, on this basis, in order to further improve the accuracy of the etching model, in the present application, a neural network unit is further added to the etching model, that is, an Artificial Intelligence (AI) unit is introduced, and etching modeling is assisted by AI, so that the etching model has a relatively high accuracy, and an accurate etching bias can be determined.

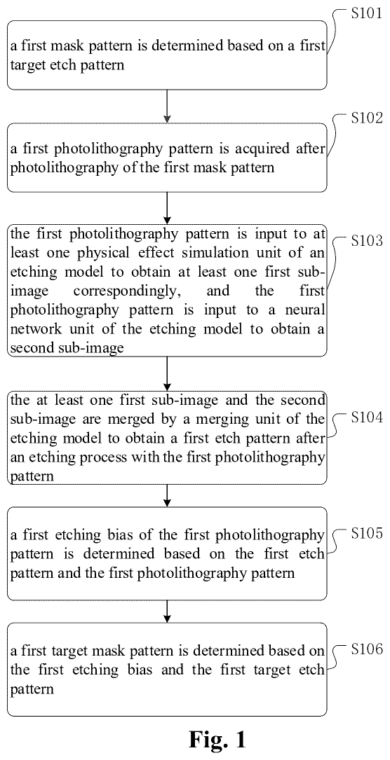

On this basis, the embodiments of the present application provide a mask pattern determination method, apparatus, medium, and product. The mask pattern determination method provided by the embodiments of the present application will be firstly described below. FIG. 1 shows a flow chart of a mask pattern determination method according to an embodiment of the present application. As shown in FIG. 1, the method may include following steps S101 to S106.

In S101, a first mask pattern is determined based on a first target etch pattern.

The present application is generally used in a mask pattern design scenario. Therefore, before acquiring a first photolithography pattern after photolithography of the first mask pattern, a first target etch pattern can be acquired, and then a first mask pattern is determined based on the first target etch pattern.

In the mask pattern design scenario, the first target etch pattern is an actually desired wafer pattern. As an optional embodiment, operations such as etching bias compensation and OPC may be performed on the first target etch pattern to obtain the first mask pattern. At this time, an etching bias can be determined through the traditional method. However, since an accuracy of the etching bias determined by the traditional method is low, in this embodiment, after the first mask pattern is obtained, the first etching bias is re-acquired based on this solution. Then, the first target mask pattern can be re-determined based on the first etching bias, and the first target mask pattern is used as a finally designed mask pattern.

In S102, a first photolithography pattern is acquired after photolithography of the first mask pattern.

The first mask pattern is a pattern on a mask, which may be a pattern in a design process or a pattern actually existing in the mask. After the mask containing the first mask pattern undergoes a photolithography process or a photolithography process simulation, a first photolithography image is obtained, and a pattern in the first photolithography image is the first photolithography pattern.

The present application is generally used in a mask pattern design scenario. During a mask pattern design process, it is necessary to first acquire a desired wafer pattern (that is, a pattern on a wafer after photolithography and etching processes), and then perform etching bias compensation and OPC on the wafer pattern to obtain the mask pattern. The above process is a common mask pattern design process. As some feasible embodiments, the first mask pattern mentioned in the present application may be the aforesaid mask pattern.

In S103, the first photolithography pattern is input to at least one physical effect simulation unit of an etching model to obtain at least one first sub-image correspondingly, and the first photolithography pattern is input to a neural network unit of the etching model to obtain a second sub-image.

The role of the etching model provided by the embodiments of the present application is to process an image to simulate an etching process, thereby obtaining an etch image after the etching is performed. The first photolithography pattern acquired above mainly represents pattern types but cannot be directly input to the etching model. Therefore, a corresponding image needs to be generated in order to simulate the etching process. In practical applications, a processor can directly generate a corresponding optical image based on pattern types of the first mask pattern, and then perform etch simulation based on an optical image of the first photolithography pattern to generate a corresponding sub-image.

The etching model in this embodiment includes a neural network unit and at least one physical effect simulation unit.

The physical effect simulation unit is configured to simulate some physical effects in an actual etching process, such as micro-loading effect and aperture effect. The mask pattern is input to different physical effect simulation units, and the first sub-image after corresponding processing can be obtained. For example, a Gaussian convolution term can be used to simulate a diffusion process.

The neural network unit is obtained by training based on a photolithography pattern sample and a corresponding etch image label. Adding the neural network unit to the etching model may greatly improve a data fitting ability of the etching model. In this manner, the problem in the existing modeling method that a desirable model calibration result cannot be quickly obtained according to a measurement result due to the complex etching process is solved. That is, the speed and accuracy of model calibration are improved.

In addition, there may be a problem of over-fitting in the neural network unit. In this embodiment, an actual physical effect is simulated by the physical effect simulation unit, which prevents the model from over-fitting. Moreover, when training the neural network unit, model training may be performed based on a large number of Scanning Electron Microscope (SEM) image data, which can further mitigate the problem of over-fitting of the neural network model.

In S104, the at least one first sub-image and the second sub-image are merged by a merging unit of the etching model to obtain a first etch pattern after an etching process with the first photolithography pattern.

After obtaining the first sub-image output by the physical effect simulation unit and the second sub-image output by the neural network unit, the images need to be merged to obtain a first etch image after the first photolithography pattern is etched. A merging process of the etching model may be specifically referred to the following formula.

$$OutputImage = {\sum }_{i = 1}^{i = n} {Term}_{i} ( InputImage ) + Neurom\_NET ( InputImage ) \qquad ( 1 )$$

Where OutputImage is the first etch image, InputImage is an optical image input to the etching model, Termi(InputImage) is the first sub-image, n is the number of the first sub-images, and Neurom_NET(InputImage) is the second sub-image.

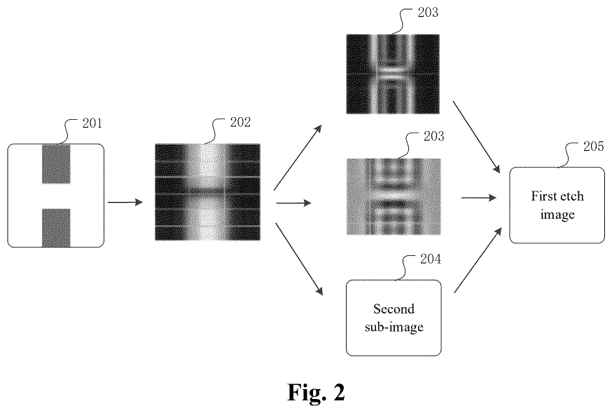

FIG. 2 shows a schematic view of a model simulation process according to an embodiment of the present application. As shown in FIG. 2, a first photolithography pattern 201 is first acquired, and then an optical image 202 of the first photolithography pattern 201 is generated. The optical image 202 is input to each physical effect simulation unit to obtain each first sub-image 203 correspondingly, and the optical image 202 is input to the neural network unit to obtain the second sub-image 204. Finally, each first sub-image 203 and the second sub-image 204 are merged by the merging unit of the etching model to obtain the first etch image 205 after an etching process with the first photolithography pattern.

For the first etch image obtained by merging the first sub-image and the second sub-image, the first etch pattern is extracted from the first etch image. As an optional embodiment, binarization processing may be performed on the first etch image based on a preset threshold to obtain the first etch pattern (that is, an etch contour).

In S105, a first etching bias of the first photolithography pattern is determined based on the first etch pattern and the first photolithography pattern.

After the first etch pattern is extracted, the first etch pattern may be compared with an original first photolithography pattern to find the difference between the two and determine the difference, that is, the etching bias. In practical applications, the pattern is usually segmented, and then when determining the first etching bias, the first etching bias corresponding to each edge segment is determined.

In S106, a first target mask pattern is determined based on the first etching bias and the first target etch pattern.

In specific implementation, the specific method on how to determine the first target mask pattern based on the first etching bias and the first target etch pattern is not limited, and corresponding solutions may be selected according to actual conditions. As an optional embodiment, the first target etch pattern is compensated based on the first etching bias to obtain a target photolithography pattern, and optical proximity correction is performed on the target photolithography pattern to obtain a first target mask pattern.

In addition, after the first etching bias is obtained, the first etching bias may be compared with the etching bias obtained by the traditional solution. When the difference between the two is relatively small, it means that the etching bias obtained by the traditional solution is sufficiently accurate. In this case, the first mask pattern can be directly used as the first target mask pattern.

In addition, as mentioned above, the pattern is usually segmented to obtain multiple edge segments, and each of the edge segments corresponds to a first etching bias. Therefore, as an optional embodiment, the above process may be performed respectively for each of the edge segments in sequence.

Since the etching bias determined by the traditional solution is not accurate, in this embodiment, after the first mask pattern is determined, the first etching bias corresponding to the first mask pattern is determined based on the etching model provided above. Since the first etching bias obtained based on the etching model is relatively accurate, the first target mask pattern that better meets actual requirements can be determined.

In addition, in practical applications, the OPC recipe and photolithography compensation and photolithography model are responsible for generating all the mask data of the corresponding process layer of this technology node, and thus they cannot be easily modified as a whole. Therefore, in the procedure of actual process development and specific chip product yield improvement, etch recipe is generally adjusted. Therefore, in practice, when the etch recipe changes, the above etching model can be dynamically adjusted based on collected silicon wafer data.

In the mask pattern determination method provided by the embodiments of the present application, the etching bias is determined by the first etch pattern and the first photolithography pattern, and the first etch image corresponding to the first etch pattern is obtained by merging the first sub-image and the second sub-image. The first sub-image is generated by the physical effect simulation unit based on the first photolithography pattern, and the second sub-image is generated by the neural network unit based on the first photolithography pattern. The neural network unit can effectively improve the data fitting ability of the etching model, thereby improving the accuracy of the etching model to obtain an accurate first etching bias. Meanwhile, the physical effect simulation unit of the etching model simulates the actual physical effect, which can prevent the etching model from over-fitting.

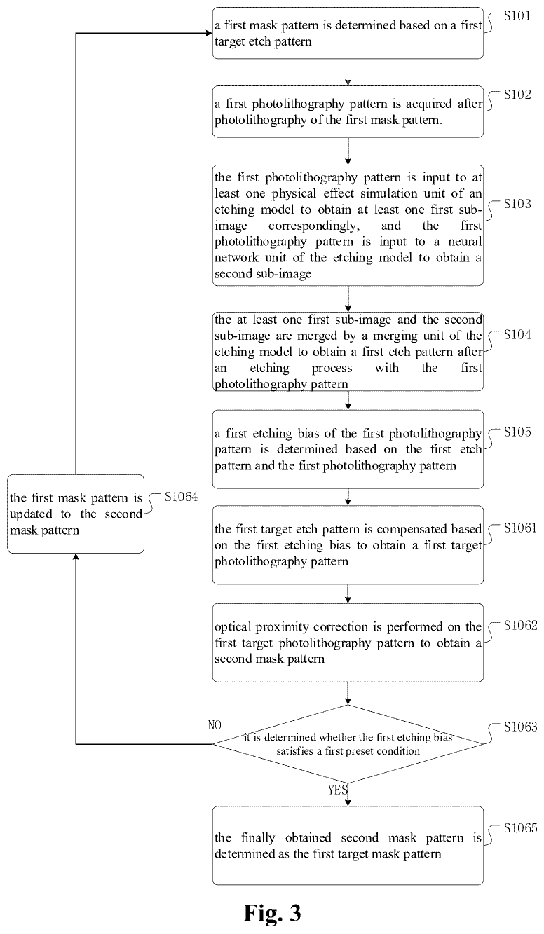

As mentioned in the above embodiments, the first target mask pattern can be determined based on the first etching bias and the first target etch pattern, and a specific determination method is provided. In practical applications, when the first etching bias is determined for the first time, the first photolithography pattern input to the etching model is obtained by the traditional method, and the accuracy is relatively low, which may lead to a result that the accuracy of the obtained first etching bias cannot meet the requirements. Therefore, another feasible embodiment is provided here. FIG. 3 shows a first flow chart of designing a first target mask pattern according to an embodiment of the present application.

As shown in FIG. 3, S106 may include following steps S1061 to S1065.

In S1061, the first target etch pattern is compensated based on the first etching bias to obtain a first target photolithography pattern.

In S1062, optical proximity correction is performed on the first target photolithography pattern to obtain a second mask pattern.

In S1063, it is determined whether the first etching bias satisfies a first preset condition; when the first etching bias does not satisfy the first preset condition, S1064 is executed; and when the first etching bias satisfies the first preset condition, S1065 is executed.

In S1064, the first mask pattern is updated to the second mask pattern; and returning to S102.

In S1065, the finally obtained second mask pattern is determined as the first target mask pattern.

In this embodiment, the accuracy of the determined first etching bias is further improved, thereby ensuring that the first target mask pattern better meets actual requirements. In this embodiment, multiple iterations may be performed to update the first mask pattern to a more accurate second mask pattern, and a more accurate first etching bias can be obtained based on the second mask pattern. In this manner, the accuracy of the second mask pattern can be continuously improved.

As an optional embodiment, the first preset condition may be that a difference between two first etching biases corresponding to two adjacent iteration processes is less than a threshold. The threshold here may be set according to actual needs. When the difference between the first etching biases corresponding to two adjacent iteration processes is not large, it means that the first etching bias obtained at this time is sufficiently accurate, and thus the iteration may be stopped. Then, the finally obtained second mask pattern is determined as the first target mask pattern.

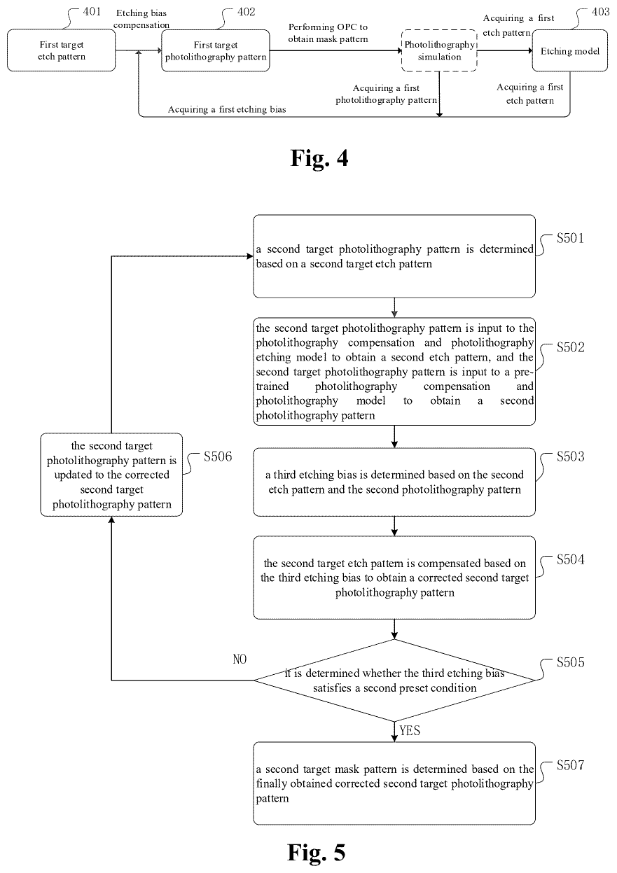

Here, a specific embodiment of designing a first target mask pattern is provided. FIG. 4 shows a second flow chart of designing a first target mask pattern according to an embodiment of the present application. As shown in FIG. 4, a first target etch pattern 401 is first acquired. An etching bias can be determined by the traditional solution and the first target etch pattern 401 is compensated to obtain a first target photolithography pattern 402. After OPC is performed, a mask pattern is obtained. A photolithography simulation is performed to obtain a first photolithography pattern, which is input to an etching model 403 for etch simulation to obtain a first etch pattern. A first etching bias is obtained based on the first photolithography pattern and the first etch pattern.

Further, after the first etching bias is obtained, the first target etch pattern 401 is compensated based on the first etching bias to obtain a new first target photolithography pattern 402. This process is repeated until the first etching bias satisfies the first preset condition, and the finally obtained mask pattern is determined as the first target mask pattern.

In the above embodiments, when the first etching bias is determined for the first time, the first photolithography pattern input to the etching model is obtained by the traditional method, and the accuracy is relatively low, which may lead to a result that the accuracy of the obtained first etching bias cannot meet the requirements. Therefore, in this embodiment, the value of the first etching bias is continuously calibrated through multiple iterations, so that the accuracy of the finally obtained first target mask pattern is higher.

As mentioned above, when using the etching model provided in the present application to determine the etching bias, it is necessary to obtain the first mask pattern in advance. However, during the process of determining the first mask pattern based on the first target etch pattern, it is necessary to obtain the etching bias to compensate the first target etch pattern, which cannot be implemented based on the etching model. Therefore, in this embodiment, the etching bias is determined for the first time by establishing a first correspondence relationship. As an optional embodiment, a step of determining the first mask pattern based on the first target etch pattern may include determining a corresponding second etching bias based on the first target etch pattern and a first correspondence relationship; compensating the first target etch pattern based on the second etching bias to obtain a corresponding first target photolithography pattern; and performing optical proximity correction based on the first target photolithography pattern to obtain the first mask pattern.

In this embodiment, the first correspondence relationship is a correspondence relationship between an etch pattern and an etching bias. As an optional embodiment, the first correspondence relationship may be implemented in a form of a table, and a correspondence relationship between different pattern types (including line width, space, among others) and etching bias is stored in the table. When etching bias needs to be determined, the pattern types corresponding to the first target etch pattern is firstly retrieved from the table, and then the corresponding second etching bias is found.

In addition, in practical applications, the first correspondence relationship can also be corrected by the etching bias obtained from the etching model to improve accuracy.

In this embodiment, the second etching bias is firstly determined according to the first correspondence relationship. Although the etching bias obtained in this manner has a low accuracy, the etching bias can meet a basic requirement for accuracy, and the solution is simple and the efficiency is relatively high.

In practical applications, the process of determining the etch pattern based on the target etch pattern requires steps such as etching bias compensation, OPC, and simulation, which is time-consuming. Therefore, an optional embodiment is provided here. After a step of merging the at least one first sub-image and the second sub-image by a merging unit of the etching model, the method may further include acquiring a first target etch pattern corresponding to the first mask pattern; constructing a training sample according to the first target etch pattern and the first etch pattern; and performing model training according to the training sample to obtain a photolithography compensation and photolithography etching model.

In this embodiment, the photolithography compensation and photolithography etching model is configured to perform OPC, photolithography simulation, etch simulation and other processes. The corresponding training data may be obtained through the above etching model. That is, the first etch pattern corresponding to the first mask pattern is obtained based on the etching model. Since the first mask pattern corresponds to the first target etch pattern, a training sample can be constructed based on a correspondence relationship between the first target etch pattern and the first etch pattern, thereby performing model training to obtain the photolithography compensation and photolithography etching model.

In this embodiment, the photolithography compensation and photolithography etching model is directly trained to complete the process from the photolithography pattern to the etch pattern. However, training the photolithography compensation and photolithography etching model requires a large amount of first etch pattern label data. In practical applications, the efficiency of acquiring label data through scanning electron microscopy is extremely low and cannot meet the needs. Therefore, in this embodiment, a large amount of training sample data is acquired through the above etching model, and then the photolithography compensation and photolithography etching model is obtained by training.

As mentioned in the above embodiments, in order to obtain the final target mask pattern, the value of the first etching bias may be calibrated by iteration for multiple times. However, each iteration requires processes such as etching bias compensation, OPC, and simulation, which is time-consuming and affects the production efficiency. Therefore, a specific embodiment is provided here. FIG. 5 shows a first flow chart of designing a second target mask pattern according to an embodiment of the present application. As shown in FIG. 5, after a step of performing model training according to the training sample to obtain the photolithography compensation and photolithography etching model, the method may further include the following steps S501 to S507.

In S501, a second target photolithography pattern is determined based on a second target etch pattern.

In S502, the second target photolithography pattern is input to the photolithography compensation and photolithography etching model to obtain a second etch pattern, and the second target photolithography pattern is input to a pre-trained photolithography compensation and photolithography model to obtain a second photolithography pattern.

In this embodiment, the photolithography compensation and photolithography etching model is configured to perform OPC, photolithography simulation, etch simulation and other processes. The photolithography compensation and photolithography model is configured to perform OPC, photolithography simulation and other processes.

At present, when determining the second etch pattern based on the second target photolithography pattern, it is necessary to firstly perform OPC to obtain a corresponding mask pattern, and then perform photolithography and etch simulation to obtain the second etch pattern. However, in this embodiment, the second etch pattern may be directly obtained based on the second target photolithography pattern through the photolithography compensation and photolithography etching model.

Correspondingly, at present, when determining the second photolithography pattern based on the second target photolithography pattern, it is necessary to firstly perform OPC to obtain a corresponding mask pattern, and then perform photolithography simulation to obtain the second photolithography pattern. However, in this embodiment, the second photolithography pattern can be directly obtained based on the second target photolithography pattern through the photolithography compensation and photolithography model.

In S503, a third etching bias is determined based on the second etch pattern and the second photolithography pattern.

In S504, the second target etch pattern is compensated based on the third etching bias to obtain a corrected second target photolithography pattern.

In S505, it is determined whether the third etching bias satisfies a second preset condition; when the third etching bias does not satisfy the second preset condition, S506 is executed; and when the third etching bias satisfies the second preset condition, S507 is executed.

In S506, the second target photolithography pattern is updated to the corrected second target photolithography pattern; and returning to S501.

In S507, a second target mask pattern is determined based on the finally obtained corrected second target photolithography pattern.

Corresponding to the first target etch pattern described above, in the mask pattern design scenario, the second target etch pattern in this embodiment is an actually desired wafer pattern, and the etching bias compensation can be performed on the first target etch pattern to obtain the second target photolithography pattern.

As mentioned above, the pattern is usually segmented, and each edge segment corresponds to a third etching bias. Therefore, as an optional embodiment, the above process may be performed respectively for each edge in sequence.

As an optional embodiment, the second preset condition may be that a difference between two third etching biases corresponding to two adjacent iteration processes is less than a threshold. The threshold here may be set according to actual needs. When the difference between the third etching biases corresponding to two adjacent iteration processes is not large, it means that the third etching bias obtained at this time is sufficiently accurate, and thus the iteration may be stopped.

When the etching bias compensation is performed for the first time, the etching bias may be determined by the traditional solution. However, since the accuracy of the etching bias determined by the traditional solution is low, in this embodiment, the third etching bias is updated by performing multiple iterations through the photolithography compensation and photolithography etching model and the photolithography compensation and photolithography model, so as to finally obtain a sufficiently accurate third etching bias, thereby obtaining an accurate second target photolithography pattern. Then, OPC is performed to obtain an actually desired second target mask pattern, and finally the second target mask pattern is used as the finally designed mask pattern.

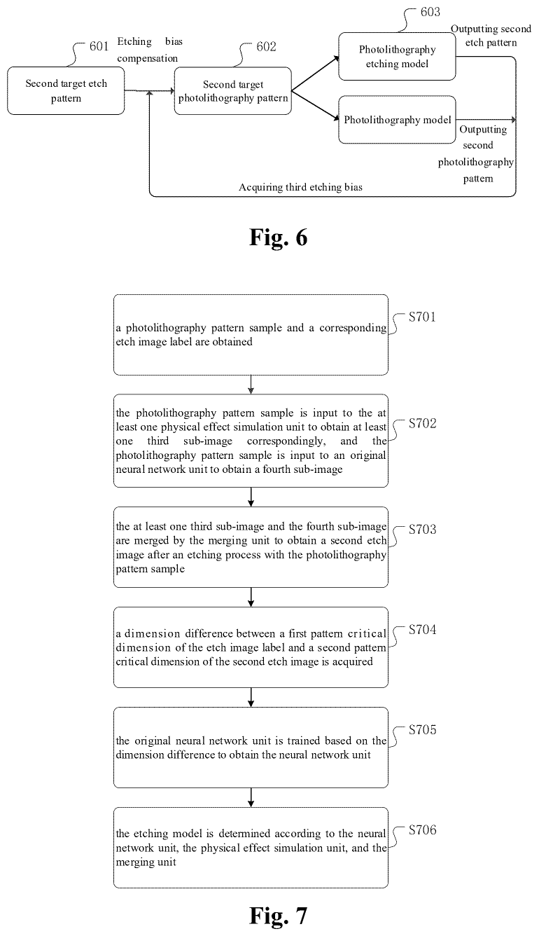

Here, a specific embodiment of designing a second target mask pattern is provided. FIG. 6 shows a second flow chart of designing a second target mask pattern according to an embodiment of the present application. As shown in FIG. 6, a second target etch pattern 601 is firstly obtained. An etching bias may be determined based on the traditional solution, and the second target etch pattern 601 is compensated to obtain a second target photolithography pattern 602. The second target photolithography pattern 602 is input to a photolithography compensation and photolithography etching model 603 and a photolithography compensation and photolithography model 604 each to obtain a second etch pattern and a second photolithography pattern correspondingly, thereby obtaining a third etching bias.

Further, after the third etching bias is obtained, the second target etch pattern 601 is compensated based on the third etching bias to obtain a new second target photolithography pattern 602, and the above process is repeated until the third etching bias satisfies the second preset condition. Finally, OPC is performed based on the finally obtained second target photolithography pattern 602 to obtain an actually desired second target mask pattern.

In this embodiment, the process from the second target photolithography pattern to the second etch pattern and the second photolithography pattern is directly completed through the photolithography compensation and photolithography etching model established in the above embodiments and the pre-trained photolithography compensation and photolithography model. Therefore, time is greatly saved in the iteration, the second target mask pattern meeting the requirements may be quickly determined, and the production efficiency is improved.

As mentioned above, when etching bias compensation is performed for the first time, etching bias may be determined by the traditional solution. As an optional embodiment, a step of determining a second target photolithography pattern based on a second target etch pattern may include determining a corresponding fourth etching bias based on the second target etch pattern and a first correspondence relationship; and compensating the second target etch pattern based on the fourth etching bias to obtain a corresponding second target photolithography pattern.

In this embodiment, the first correspondence relationship is a correspondence relationship between an etch pattern and an etching bias. As an optional embodiment, the first correspondence relationship may be implemented in a form of a table, and a correspondence relationship between different pattern types (including line width, space, among others) and etching bias is stored in the table. When the etching bias needs to be determined, the pattern types corresponding to the second target etch pattern is firstly retrieved from the table, and then the corresponding fourth etching bias is found.

In this embodiment, the fourth etching bias is firstly determined according to the first correspondence relationship. Although the etching bias obtained in this manner has a low accuracy, the etching bias can meet a basic requirement for accuracy, and the solution is simple and the efficiency is relatively high.

As mentioned in the above embodiments, the etching model provided by the present application includes a neural network unit and at least one physical effect simulation unit, wherein the neural network unit needs to be trained to ensure that the etching model outputs accurate results. Therefore, an optional embodiment is provided here. FIG. 7 shows a flow chart of training an etching model according to an embodiment of the present application. As shown in FIG. 7, before using the etching model, the method further includes the following steps S701 to S706.

In S701, a photolithography pattern sample and a corresponding etch image label are obtained.

In S702, the photolithography pattern sample is input to the at least one physical effect simulation unit to obtain at least one third sub-image correspondingly, and the photolithography pattern sample is input to an original neural network unit to obtain a fourth sub-image.

In S703, the at least one third sub-image and the fourth sub-image are merged by the merging unit to obtain a second etch image after an etching process with the photolithography pattern sample.

In S704, a dimension difference between a first pattern critical dimension of the etch image label and a second pattern critical dimension of the second etch image is acquired.

In S705, the original neural network unit is trained based on the dimension difference to obtain the neural network unit.

In S706, the etching model is determined according to the neural network unit, the physical effect simulation unit, and the merging unit.

In this embodiment, the photolithography pattern sample corresponds to the etch image label, and the etch image label is obtained after the photolithography pattern sample is etched. Therefore, the neural network unit is trained through the photolithography pattern sample and the corresponding etch image label, so that the etching model can output accurate results.

The first pattern critical dimension mentioned in this embodiment is a critical dimension corresponding to a pattern in the etch image label, and the second pattern critical dimension is a critical dimension corresponding to a pattern in the second etch image, which can be obtained by calculating based on the corresponding patterns. The calculated first pattern critical dimension and the second pattern critical dimension are compared to obtain the dimension difference, and whether the model converges is determined based on an evaluation function. In a case that the model does not converge, the types of the original neural network unit can be adjusted by iteration for multiple times, and finally a neural network unit meeting requirements is obtained. In addition, in practical applications, a combination of physical effect simulation units may also be adjusted through the above training method, thereby optimizing and adjusting the entire etching model.

In the process of determining whether the model converges based on the evaluation function, the evaluation can also be carried out for each edge of the pattern. As an optional embodiment, an evaluation point may be set on an edge that needs to be evaluated, and then positions of the evaluation points of two patterns at the same position are compared, and an evaluation function value is determined based on a distance difference, so as to determine whether an output result of the model is accurate.

It is also mentioned in the above embodiments that, the etch recipe often changes in practice. When the etch recipe changes, the above etching model can be dynamically adjusted based on collected silicon wafer data. In the present application, model training can be performed through actual data, and a new etching model can be quickly obtained, thereby improving production efficiency.

Furthermore, automatic and continuous modeling can also be achieved. By continuously collecting SEM images during the actual production process, the etching model may be automatically updated after the process changes. For example, a wafer image after being etched in actual production may be obtained through SEM, then a pattern contour of each SEM image may be extracted as the etch image label, and a corresponding photolithography pattern can be used as the photolithography pattern sample for training the model.

This embodiment provides a method for training an etching model, which trains an original neural network unit through the photolithography pattern sample and the corresponding etch pattern label, and adjusts the neural network unit when there is a difference between a simulation image and a label image, thereby enabling the etching model to output results consistent with reality.

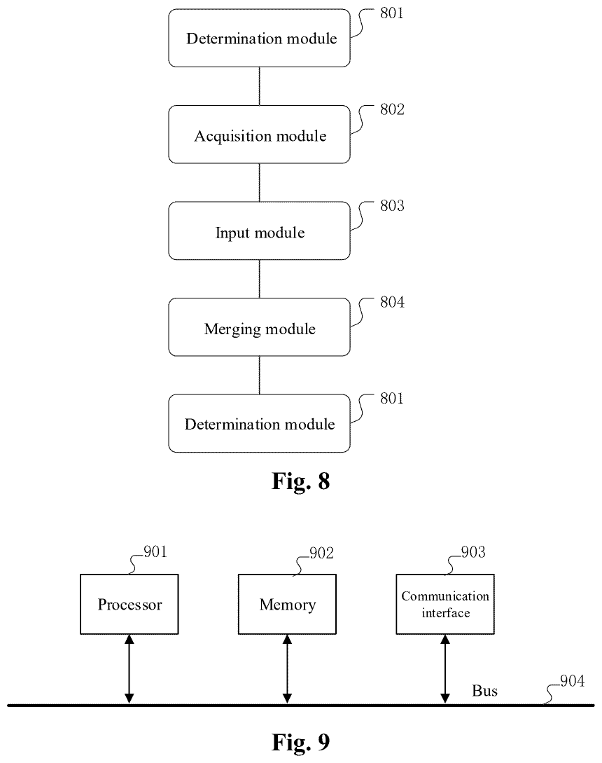

Based on the mask pattern determination method provided in the above embodiments, correspondingly, the embodiments of the present application further provide a mask pattern determination apparatus. FIG. 8 shows a schematic structural view of a mask pattern determination apparatus according to an embodiment of the present application. As shown in FIG. 8, the apparatus includes the following modules a determination module 801, configured to determine a first mask pattern based on a first target etch pattern; an acquisition module 802, configured to acquire a first photolithography pattern after photolithography of the first mask pattern; an input module 803, configured to input the first photolithography pattern to at least one physical effect simulation unit of an etching model to obtain at least one first sub-image correspondingly, and input the first photolithography pattern to a neural network unit of the etching model to obtain a second sub-image, the neural network unit being trained based on a photolithography pattern sample and a corresponding etch image label; a merging module 804, configured to merge the at least one first sub-image and the second sub-image by a merging unit of the etching model to obtain a first etch pattern after an etching process with the first photolithography pattern; a determination module 801, further configured to determine a first etching bias of the first photolithography pattern based on the first etch pattern and the first photolithography pattern; and a determination module 801, further configured to determine a first target mask pattern based on the first etching bias and the first target etch pattern.

The apparatus provided in the embodiments of the present application corresponds to the method in the aforesaid embodiments. Therefore, the apparatus and the method have the same embodiments and beneficial effects, and details are not repeated here.

In some embodiments, the determination module 801 is specifically configured to compensate the first target etch pattern based on the first etching bias to obtain a first target photolithography pattern; perform optical proximity correction based on the first target photolithography pattern to obtain a second mask pattern; update the first mask pattern to the second mask pattern, and return to acquiring a first photolithography pattern after photolithography of the first mask pattern until the first etching bias satisfies the first preset condition; and determine a finally obtained second mask pattern as the first target mask pattern.

In this embodiment, a value of the first etching bias is continuously calibrated through multiple iterations, so that the accuracy of the final first target mask pattern is higher.

In some embodiments, the determination module 801 is specifically configured to determine a corresponding second etching bias based on the first target etch pattern and a first correspondence relationship, the first correspondence relationship being a correspondence relationship between an etch pattern and an etching bias; compensate the first target etch pattern based on the second etching bias to obtain a corresponding first target photolithography pattern; and perform optical proximity correction based on the first target photolithography pattern to obtain the first mask pattern.

In this implementation, the second etching bias is first determined by using the first correspondence relationship, which is simple in solution and relatively high in efficiency.

In some embodiments, the acquisition module 802 is further configured to acquire a first target etch pattern corresponding to the first mask pattern after a step of merging the at least one first sub-image and the second sub-image by a merging unit of the etching model.

The mask pattern determination apparatus further includes a construction module configured to construct a training sample according to the first target etch pattern and the first etch pattern; and a training module configured to perform model training according to the training sample to obtain a photolithography compensation and photolithography etching model.

In this embodiment, a large amount of training sample data is obtained through the above etching model, and then a relatively accurate photolithography compensation and photolithography etching model may be obtained by training.

In some embodiments, the determination module 801 is further configured to determine a second target photolithography pattern based on a second target etch pattern after a step of performing model training according to the training sample to obtain a photolithography compensation and photolithography etching model.

The input module 803 is further configured to input the second target photolithography pattern to the photolithography compensation and photolithography etching model to obtain a second etch pattern, and input the second target photolithography pattern to a pre-trained photolithography compensation and photolithography model to obtain a second photolithography pattern.

The determination module 801 is further configured to determine a third etching bias based on the second etch pattern and the second photolithography pattern.

The mask pattern determination apparatus further includes a compensation module configured to compensate the second target etch pattern based on the third etching bias to obtain a corrected second target photolithography pattern; and an updating module configured to update the second target photolithography pattern to the corrected second target photolithography pattern, and return to inputting the second target photolithography pattern to the photolithography compensation and photolithography etching model to obtain a second etch pattern, and inputting the second target photolithography pattern to a pre-trained photolithography compensation and photolithography model to obtain a second photolithography pattern until the third etching bias satisfies the second preset condition.

A second target mask pattern is determined based on a finally obtained corrected second target photolithography pattern.

In this embodiment, a lot of time is saved in the iteration, the second target mask pattern meeting the requirements can be quickly determined, and the production efficiency is improved.

In some embodiments, the determination module 801 is specifically configured to determine a corresponding fourth etching bias based on the second target etch pattern and a first correspondence relationship, the first correspondence relationship being a correspondence relationship between an etch pattern and an etching bias; and compensate the second target etch pattern based on the fourth etching bias to obtain a corresponding second target photolithography pattern.

In this embodiment, the solution for determining the etching bias is simple and has a relatively high efficiency.

In some embodiments, the acquisition module 802 is further configured to acquire a photolithography pattern sample and a corresponding etch image label before inputting the first photolithography pattern to at least one physical effect simulation unit of an etching model to obtain at least one first sub-image correspondingly, and inputting the first photolithography pattern to a neural network unit of the etching model to obtain a second sub-image.

The input module 803 is further configured to input the photolithography pattern sample to the at least one physical effect simulation unit to obtain at least one third sub-image correspondingly, and input the photolithography pattern sample to an original neural network unit to obtain a fourth sub-image.

The merging module 804 is further configured to merge the at least one third sub-image and the fourth sub-image by the merging unit to obtain a second etch image after an etching process with the photolithography pattern sample.

The acquisition module 802 is further configured to acquire a dimension difference between a first pattern critical dimension of the etch image label and a second pattern critical dimension of the second etch image.

The training module is further configured to train the original neural network unit based on the dimension difference to obtain the neural network unit.

The determination module 801 is further configured to determine the etching model according to the neural network unit, the physical effect simulation unit, and the merging unit.

In this embodiment, the original neural network unit is trained through the photolithography pattern sample and the corresponding etch pattern label, and thus the etching model can output accurate results consistent with reality.

FIG. 9 shows a schematic structural view of a hardware of a mask pattern determination apparatus according to an embodiment of the present application. As shown in FIG. 9, the mask pattern determination apparatus may include a processor 901 and a memory 902 storing computer program instructions.

Specifically, the processor 901 may include a Central Processing Unit (CPU), or an Application Specific Integrated Circuit (ASIC), or may be configured as one or more integrated circuits for implementing the embodiments of the present application.

Memory 902 may include mass memory for data or instructions. By way of example but not limitation, the memory 902 may include the Hard Disk Drive (HDD), the floppy disk drive, the flash memory, the optical disk, the magneto-optical disk, the magnetic tape, or the Universal Serial Bus (USB) drive, or a combination of two or more thereof. Where appropriate, the memory 902 may include the removable or non-removable (or fixed) medium. Where appropriate, the memory 902 may be internal or external to the integrated gateway disaster recovery device. In a particular embodiment, the memory 902 is the non-volatile solid state memory.

The memory 902 may include the Read-Only Memory (ROM), the Random Access Memory (RAM), the magnetic disk storage medium device, the optical storage medium device, the flash memory device, the electrical, optical, or other physical/tangible memory storage device. Accordingly, the memory 902 generally includes one or more tangible (non-transitory) computer-readable storage media (such as, memory device) of software that may be encoded with computer-executable instructions and, the software, when executed (for example by one or more processors), is operable to perform the operations described in the methods according to the above aspects of the present application.

The processor 901 implements any one of the mask pattern determination methods in the above embodiments by reading and executing the computer program instructions stored in the memory 902.

In an example, the mask pattern determination apparatus may further include a communication interface 903 and a bus 904. The processor 901, the memory 902, and the communication interface 903 are connected to each other by the bus 904 and communicate with each other.

The communication interface 903 is mainly configured to implement communication between various modules, apparatus, units and/or devices in the embodiments of the present application.

The bus 904 includes hardware, software or both thereof for coupling the components of the mask pattern determination apparatus to each other. By way of example but not limitation, the bus may include Accelerated Graphical Port (AGP) or other graphical bus, Enhanced Industry Standard Architecture (EISA) bus, Front Side Bus (FSB), Hyper Transport (HT) interconnect, Industry Standard Architecture (ISA) bus, the infinite bandwidth interconnect, Low Pin Count (LPC) bus, memory bus, Micro Channel Architecture (MCA) bus, Peripheral Component Interconnect (PCI) bus, PCI-Express (PCI-X) bus, Serial Advanced Technology Attachment (SATA) bus, Video Electronics Standards Association Local Bus (VLB) bus, or other suitable bus, or a combination of two or more thereof. Where appropriate, the bus 904 may include one or more buses. Although the embodiments of the present application describe and illustrate particular buses, any suitable bus or interconnect is contemplated by the present application.

In addition, the embodiments of the present application may provide a computer storage medium for implementing the mask pattern determination method in the above embodiments. The computer storage medium has stored thereon computer program instructions which, when executed by a processor, implement any one of the mask pattern determination methods in the above embodiments.

The embodiments of the present application further provide a computer program product including a computer program which, when executed by a processor, implements any one of the mask pattern determination methods in the above embodiments.

It should be noted that, the present application is not limited to the specific configurations and processes described above and illustrated in the drawings. For the sake of brevity, a detailed description of known methods is omitted here. In the embodiments described above, a number of specific steps have been described and shown as examples. However, the method processes of the present application are not limited to the specific steps described and illustrated herein, and those skilled in the art can make various changes, modifications, and additions, or change the order between steps, after understanding the gist of the present application.

The functional blocks shown in the block diagrams described above may be implemented in hardware, software, firmware, or a combination thereof. When implemented in hardware, it may be, for example, an electronic circuit, an ASIC, appropriate firmware, a plug-in, a function card, and so on. When implemented in software, the elements of the present application are programs or code segments used to perform the required tasks. The programs or code segments may be stored in a machine-readable medium or transmitted over a transmission medium or communication link by a data signal carried in a carrier wave. The “machine-readable medium” may include any medium that can store or transmit information. Examples of the machine-readable medium include an electronic circuit, a semiconductor memory device, an ROM, a flash memory, an Erasable ROM (EROM), a floppy disk, a Compact Disc Read-Only Memory (CD-ROM), an optical disk, a hard disk, an optical fiber medium, a Radio Frequency (RF) link, and so on. The code segments may be downloaded via a computer network, such as the Internet, an intranet, or the like.

It should also be noted that, the exemplary embodiments mentioned in the present application describe methods or systems based on a series of steps or apparatus. However, the present application is not limited to the order of the steps described above, that is, the steps may be performed in the order mentioned in the embodiments, or may be performed in an order different from that in the embodiments, or several steps may be performed at the same time.

Aspects of the present application are described above with reference to flow charts and/or block diagrams of the mask pattern determination method, the mask pattern determination apparatus, the medium, and the product according to embodiments of the present disclosure. It should be understood that, each block in the flow charts and/or block diagrams, and a combination of any of blocks in the flow charts and/or block diagrams, may be implemented by computer program instructions. These computer program instructions may be provided to a processor of a general purpose computer, a special purpose computer, or other programmable data processing apparatus to produce a machine, so that the instructions, which being executed via the processor of the computer or other programmable data processing apparatus, enable the implementation of the functions/actions specified in one or more blocks in the flow charts and/or block diagrams. Such a processor may be, but is not limited to, a general purpose processor, a special purpose processor, an application specific processor, or field programmable logic circuit. It should also be understood that, each block in the block diagrams and/or flow charts, and a combination of any of blocks in the block diagrams and/or flow charts, may also be implemented by a special purpose hardware that performs the specified functions or actions, or a combination of special purpose hardware and computer instructions.

The above are only specific implementations of the present application. Those skilled in the art can clearly understand that, for the convenience and brevity of the description, the specific working processes of the above-described systems, modules and units can be referred to the corresponding processes in the foregoing method embodiments, which is not repeated here. It should be understood that, the protection scope of the present application is not limited to this, and those skilled in the art can easily think of various equivalent modifications or replacements within the technical scope disclosed in the present application, and these modifications or replacements should all be covered within the scope of protection of the present application.

What is claimed is:

1. A mask pattern determination method, comprising:
determining a first mask pattern based on a first target etch pattern;
acquiring a first photolithography pattern after photolithography with the first mask pattern;
inputting the first photolithography pattern to at least one physical effect simulation unit of an etching model to obtain at least one first sub-image correspondingly, and inputting the first photolithography pattern to a neural network unit of the etching model to obtain a second sub-image, wherein the neural network unit is trained based on a photolithography pattern sample and a corresponding etch image label;
merging the at least one first sub-image and the second sub-image by a merging unit of the etching model to obtain a first etch pattern after an etching process with the first photolithography pattern;
determining a first etching bias of the first photolithography pattern based on the first etch pattern and the first photolithography pattern; and
determining a first target mask pattern based on the first etching bias and the first target etch pattern.

2. The mask pattern determination method according to claim 1, wherein the determining a first target mask pattern based on the first etching bias and the first target etch pattern comprises:
compensating the first target etch pattern based on the first etching bias to obtain a first target photolithography pattern;
performing optical proximity correction based on the first target photolithography pattern to obtain a second mask pattern;
updating the first mask pattern to the second mask pattern in a case that the first etching bias does not satisfy a first preset condition, and returning to the step of the acquiring a first photolithography pattern after photolithography with the first mask pattern until the first etching bias satisfies the first preset condition;
determining the current second mask pattern as the first target mask pattern in a case that the first etching bias satisfies the first preset condition.

3. The mask pattern determination method according to claim 1, wherein the determining a first mask pattern based on a first target etch pattern comprises:
determining a corresponding second etching bias based on the first target etch pattern and a first correspondence relationship, the first correspondence relationship being a correspondence relationship between an etch pattern and an etching bias;
compensating the first target etch pattern based on the second etching bias to obtain a corresponding first target photolithography pattern; and
performing optical proximity correction based on the first target photolithography pattern to obtain the first mask pattern.

4. The mask pattern determination method according to claim 1, wherein after the merging the at least one first sub-image and the second sub-image by a merging unit of the etching model, the method further comprises:
acquiring a first target etch pattern corresponding to the first mask pattern;
constructing a training sample according to the first target etch pattern and the first etch pattern; and
performing model training according to the training sample to obtain a photolithography compensation and photolithography etching model.

5. The mask pattern determination method according to claim 4, wherein after the performing model training according to the training sample to obtain a photolithography compensation and photolithography etching model, the method further comprises:
determining a second target photolithography pattern based on a second target etch pattern;
inputting the second target photolithography pattern to the photolithography compensation and photolithography etching model to obtain a second etch pattern, and inputting the second target photolithography pattern to a pre-trained photolithography compensation and photolithography model to obtain a second photolithography pattern;
determining a third etching bias based on the second etch pattern and the second photolithography pattern;
in a case that the third etching bias does not satisfy the second preset condition, compensating the second target etch pattern based on the third etching bias, so as to obtain a corrected second target photolithography pattern;
updating the second target photolithography pattern to the corrected second target photolithography pattern, and returning to the step of inputting the second target photolithography pattern to the photolithography compensation and photolithography etching model to obtain a second etch pattern and inputting the second target photolithography pattern to a pre-trained photolithography compensation and photolithography model to obtain a second photolithography pattern until the third etching bias satisfies the second preset condition; and
determining a second target mask pattern based on the current corrected second target photolithography pattern in a case that the third etching bias satisfies the second preset condition.

6. The mask pattern determination method according to claim 5, wherein the determining a second target photolithography pattern based on a second target etch pattern comprises:
determining a corresponding fourth etching bias based on the second target etch pattern and a first correspondence relationship, the first correspondence relationship being a correspondence relationship between an etch pattern and an etching bias; and
compensating the second target etch pattern based on the fourth etching bias to obtain the corresponding second target photolithography pattern.

7. The mask pattern determination method according to claim 1, wherein before the inputting the first photolithography pattern to at least one physical effect simulation unit of an etching model to obtain at least one first sub-image correspondingly and inputting the first photolithography pattern to a neural network unit of the etching model to obtain a second sub-image, the method further comprises:
acquiring the photolithography pattern sample and the corresponding etch image label;
inputting the photolithography pattern sample to the at least one physical effect simulation unit to obtain at least one third sub-image correspondingly, and inputting the photolithography pattern sample to an original neural network unit to obtain a fourth sub-image;
merging the at least one third sub-image and the fourth sub-image by the merging unit to obtain a second etch image after an etching process with the photolithography pattern sample;
acquiring a dimension difference between a first pattern critical dimension of the etch image label and a second pattern critical dimension of the second etch image;
training the original neural network unit based on the dimension difference, so as to obtain the neural network unit; and
determining the etching model according to the neural network unit, the physical effect simulation unit, and the merging unit.

8. The mask pattern determination method according to claim 2, wherein before the inputting the first photolithography pattern to at least one physical effect simulation unit of an etching model to obtain at least one first sub-image correspondingly and inputting the first photolithography pattern to a neural network unit of the etching model to obtain a second sub-image, the method further comprises:
acquiring the photolithography pattern sample and the corresponding etch image label;
inputting the photolithography pattern sample to the at least one physical effect simulation unit to obtain at least one third sub-image correspondingly, and inputting the photolithography pattern sample to an original neural network unit to obtain a fourth sub-image;
merging the at least one third sub-image and the fourth sub-image by the merging unit to obtain a second etch image after an etching process with the photolithography pattern sample;
acquiring a dimension difference between a first pattern critical dimension of the etch image label and a second pattern critical dimension of the second etch image;
training the original neural network unit based on the dimension difference, so as to obtain the neural network unit; and
determining the etching model according to the neural network unit, the physical effect simulation unit, and the merging unit.

9. The mask pattern determination method according to claim 3, wherein before the inputting the first photolithography pattern to at least one physical effect simulation unit of an etching model to obtain at least one first sub-image correspondingly and inputting the first photolithography pattern to a neural network unit of the etching model to obtain a second sub-image, the method further comprises:
acquiring the photolithography pattern sample and the corresponding etch image label;
inputting the photolithography pattern sample to the at least one physical effect simulation unit to obtain at least one third sub-image correspondingly, and inputting the photolithography pattern sample to an original neural network unit to obtain a fourth sub-image;
merging the at least one third sub-image and the fourth sub-image by the merging unit to obtain a second etch image after an etching process with the photolithography pattern sample;
acquiring a dimension difference between a first pattern critical dimension of the etch image label and a second pattern critical dimension of the second etch image;
training the original neural network unit based on the dimension difference, so as to obtain the neural network unit; and
determining the etching model according to the neural network unit, the physical effect simulation unit, and the merging unit.

10. The mask pattern determination method according to claim 4, wherein before the inputting the first photolithography pattern to at least one physical effect simulation unit of an etching model to obtain at least one first sub-image correspondingly and inputting the first photolithography pattern to a neural network unit of the etching model to obtain a second sub-image, the method further comprises:
acquiring the photolithography pattern sample and the corresponding etch image label;
inputting the photolithography pattern sample to the at least one physical effect simulation unit to obtain at least one third sub-image correspondingly, and inputting the photolithography pattern sample to an original neural network unit to obtain a fourth sub-image;
merging the at least one third sub-image and the fourth sub-image by the merging unit to obtain a second etch image after an etching process with the photolithography pattern sample;
acquiring a dimension difference between a first pattern critical dimension of the etch image label and a second pattern critical dimension of the second etch image;
training the original neural network unit based on the dimension difference, so as to obtain the neural network unit; and
determining the etching model according to the neural network unit, the physical effect simulation unit, and the merging unit.

11. The mask pattern determination method according to claim 5, wherein before the inputting the first photolithography pattern to at least one physical effect simulation unit of an etching model to obtain at least one first sub-image correspondingly and inputting the first photolithography pattern to a neural network unit of the etching model to obtain a second sub-image, the method further comprises:
acquiring the photolithography pattern sample and the corresponding etch image label;
inputting the photolithography pattern sample to the at least one physical effect simulation unit to obtain at least one third sub-image correspondingly, and inputting the photolithography pattern sample to an original neural network unit to obtain a fourth sub-image;
merging the at least one third sub-image and the fourth sub-image by the merging unit to obtain a second etch image after an etching process with the photolithography pattern sample;
acquiring a dimension difference between a first pattern critical dimension of the etch image label and a second pattern critical dimension of the second etch image;
training the original neural network unit based on the dimension difference, so as to obtain the neural network unit; and
determining the etching model according to the neural network unit, the physical effect simulation unit, and the merging unit.

12. The mask pattern determination method according to claim 6, wherein before the inputting the first photolithography pattern to at least one physical effect simulation unit of an etching model to obtain at least one first sub-image correspondingly and inputting the first photolithography pattern to a neural network unit of the etching model to obtain a second sub-image, the method further comprises:
acquiring the photolithography pattern sample and the corresponding etch image label;
inputting the photolithography pattern sample to the at least one physical effect simulation unit to obtain at least one third sub-image correspondingly, and inputting the photolithography pattern sample to an original neural network unit to obtain a fourth sub-image;
merging the at least one third sub-image and the fourth sub-image by the merging unit to obtain a second etch image after an etching process with the photolithography pattern sample;
acquiring a dimension difference between a first pattern critical dimension of the etch image label and a second pattern critical dimension of the second etch image;
training the original neural network unit based on the dimension difference, so as to obtain the neural network unit; and
determining the etching model according to the neural network unit, the physical effect simulation unit, and the merging unit.

13. A mask pattern determination apparatus, comprising a processor and a memory storing computer program instructions, wherein the processor, when executes the computer program instructions, implements a mask pattern determination method comprising: determining a first mask pattern based on a first target etch pattern; acquiring a first photolithography pattern after photolithography with the first mask pattern; inputting the first photolithography pattern to at least one physical effect simulation unit of an etching model to obtain at least one first sub-image correspondingly, and inputting the first photolithography pattern to a neural network unit of the etching model to obtain a second sub-image, wherein the neural network unit is trained based on a photolithography pattern sample and a corresponding etch image label; merging the at least one first sub-image and the second sub-image by a merging unit of the etching model to obtain a first etch pattern after an etching process with the first photolithography pattern; determining a first etching bias of the first photolithography pattern based on the first etch pattern and the first photolithography pattern; and determining a first target mask pattern based on the first etching bias and the first target etch pattern.

14. A non-transitory computer-readable storage medium, storing computer program instructions, when executed by a processor, implement a mask pattern determination method comprising: determining a first mask pattern based on a first target etch pattern; acquiring a first photolithography pattern after photolithography with the first mask pattern; inputting the first photolithography pattern to at least one physical effect simulation unit of an etching model to obtain at least one first sub-image correspondingly, and inputting the first photolithography pattern to a neural network unit of the etching model to obtain a second sub-image, wherein the neural network unit is trained based on a photolithography pattern sample and a corresponding etch image label; merging the at least one first sub-image and the second sub-image by a merging unit of the etching model to obtain a first etch pattern after an etching process with the first photolithography pattern; determining a first etching bias of the first photolithography pattern based on the first etch pattern and the first photolithography pattern; and determining a first target mask pattern based on the first etching bias and the first target etch pattern.

15. A computer program product, wherein instructions in the computer program product, when executed by a processor of an electronic device, enable the electronic device to execute the mask pattern determination method according to claim 1.
